(19) United States
(12) Patent Application Publication
(10) Pub. No.: US 2014/0345525 A1
(43) Pub. Date: Nov. 27, 2014

(54) COATED LINER ASSEMBLY FOR A SEMICONDUCTOR PROCESSING CHAMBER

(71) Applicant: Applied Materials, Inc., Santa Clara, CA (US)

(72) Inventors: Joseph M. RANISH, San Jose, CA (US); Satheesh KUPPURAO, San Jose, CA (US); Kailash Kiran PATALAY, Santa Clara, CA (US); Paul BRILLHART, Pleasanton, CA (US)

(73) Assignee: Applied Materials, Inc., Santa Clara, CA (US)

(21) Appl. No.: 14/272,428

(22) Filed: May 7, 2014

Related U.S. Application Data
(60) Provisional application No. 61/826,680, filed on May 23, 2013.

(51) Int. Cl. H01L 21/02

(52) U.S. Cl. CPC H01L 21/02293
USPC 118/715

(57) ABSTRACT

Embodiments disclosed herein relate to coated liner assemblies for use in a semiconductor processing chamber. In one embodiment, a liner assembly for use in a semiconductor processing chamber includes a liner body having a cylindrical ring form and a coating layer coating the liner body, wherein the coating layer is opaque at one or more wavelengths between about 200 nm and about 5000 nm. In another embodiment, an apparatus for depositing a dielectric layer on a substrate includes a processing chamber having an interior volume defined in a chamber body of the processing chamber, a liner assembly disposed in the processing chamber, wherein the liner assembly further comprises a liner body having a cylindrical ring form, and a coating layer coating an outer wall of the liner body and facing the chamber body, wherein the coating layer is opaque at one or more wavelengths between about 200 nm and about 5000 nm.

### CROSS-REFERENCE TO RELATED APPLICATIONS

This application claims benefit of U.S. Provisional Application Ser. No. 61/826,680 filed May 23, 2013 (Attorney Docket No. APPM/20341L), which is incorporated by reference in its entirety.

### FIELD

An apparatus for semiconductor processing is disclosed herein. More specifically, embodiments disclosed herein relate to a coated liner assembly for use in a semiconductor processing chamber.

### BACKGROUND

Semiconductor substrates are processed for a wide variety of applications, including the fabrication of integrated devices and microdevices. One method of processing substrates includes depositing a material, such as a dielectric material or a conductive metal, on an upper surface of the substrate. Epitaxy is one of the deposition processes that is used extensively in semiconductor processing to form thin material layers on semiconductor substrates. These layers frequently define some of the small features of a semiconductor device, and they may be required to have a high quality crystal structure if the electrical properties of crystalline materials are desired. A deposition precursor is normally provided to a processing chamber in which a substrate is disposed. The substrate is then heated to a temperature that favors growth of a material layer having desired properties.

It is usually desired that the deposited film have uniform thickness, composition, and structure across the surface of the substrate. Variations in local substrate temperature, gas flows, and precursor concentrations may result in the deposited film formed on the substrate having non-uniform film thickness, non-uniform and unrepeatable film properties. During processing, the processing chamber is normally maintained at vacuum, typically below 10 Torr. Thermal energy utilized to heat the substrate is often provided by heat lamps positioned outside the processing chamber to avoid introducing contaminants. Pyrometers are utilized in the processing chamber to measure the temperature of the substrate. However, accurate measurement of substrate temperature is difficult due to artifacts from scattered radiant energy from the heating sources.

Therefore, there remains a need for an epitaxy processing chamber with improved temperature control, temperature measurement, and methods of operating such a chamber to improve deposition uniformity and repeatability.

### SUMMARY

Embodiments disclosed herein relate to coated liner assemblies for use in a semiconductor processing chamber. In one embodiment, a liner assembly for use in a semiconductor processing chamber includes a liner body having a cylindrical ring form and a coating layer coating the liner body, wherein the coating layer is opaque at one or more wavelengths between about 200 nm and about 5000 nm.

In another embodiment, an apparatus for depositing a dielectric layer on a substrate includes a processing chamber having an interior volume defined in a chamber body of the processing chamber, a liner assembly disposed in the processing chamber, wherein the liner assembly further comprises a liner body having a cylindrical ring form, and a coating layer coating an outer wall of the liner body and facing the chamber body, wherein the coating layer is opaque at one or more wavelengths between about 200 nm and about 5000 nm.

In yet another embodiment, an apparatus for depositing a dielectric layer on a substrate includes a processing chamber having an interior volume defined in a chamber body of the processing chamber, a liner assembly disposed in the processing chamber, wherein the liner assembly further comprises a liner body having a cylindrical ring form, and a coating layer coating on an outer wall of the liner body and facing the chamber body, wherein the coating layer is opaque at one or more wavelengths between about 200 nm and about 5000 nm, the coating layer fabricated from a material selected from the silicon carbide, glassy carbon, carbon black, graphitized carbon black, graphite, black quartz, bubble quartz, silicon and black pigmented slip coating.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a processing chamber according to one embodiment of the invention;

FIG. 2A depicted a schematic top isometric view of a liner assembly that may be used in the processing chamber of FIG. 1;

FIG. 2B depicts a cross-sectional view of the liner assembly depicted in FIG. 2A;

FIG. 3A depicted a schematic top isometric view of another liner assembly that may be used in the processing chamber of FIG. 1; and

FIG. 3B depicts a cross-sectional view of the liner assembly depicted in FIG. 3A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to an apparatus and methods for depositing materials on a substrate, the apparatus having a coated liner assembly. The coated liner assembly may assist absorbing light reflected from the adjacent environment, so as to minimize interference that may diminish the accuracy of temperature measurement obtained using a pyrometer disposed on the processing chamber during a substrate temperature measurement process. In one embodiment, the liner assembly may have a coating layer fabricated from a dielectric material which is opaque at one or more wavelengths between about 200 nm and about 5000 nm.

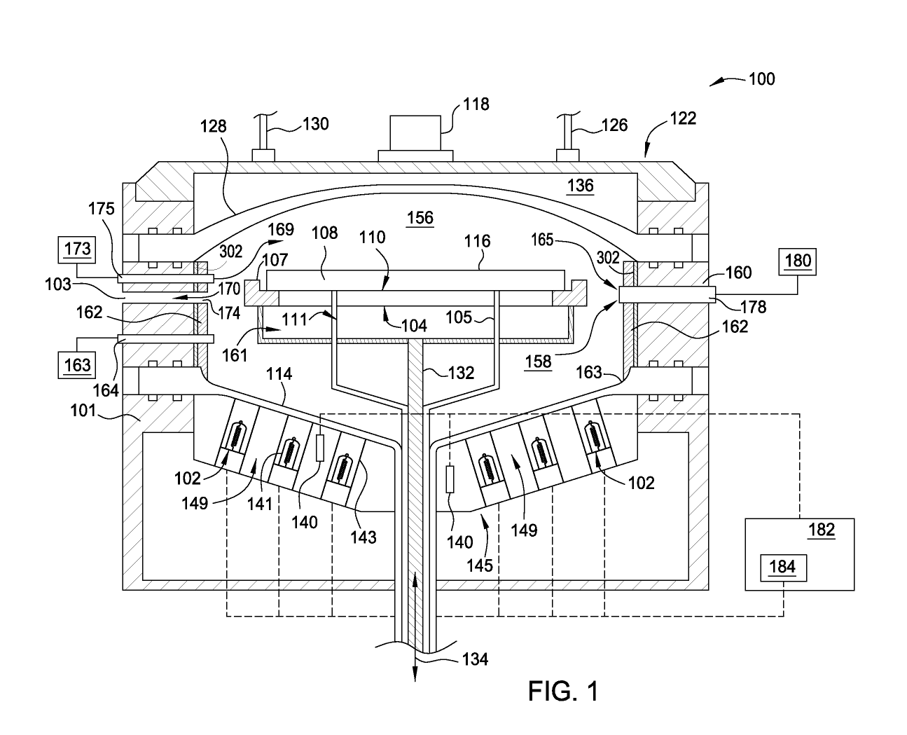

FIG. 1 is a schematic sectional view of a processing chamber 100 according to one embodiment of the invention. The processing chamber 100 may be used to process one or more substrates, including deposition of a material on an upper surface of a substrate, such as an upper surface 116 of a substrate 108 depicted in FIG. 1. The processing chamber 100 includes a chamber body 101 connected to, an upper dome 128 and a lower dome 114. In one embodiment, the upper dome 128 may be fabricated from a material such as a stainless steel, aluminum, or ceramics including quartz, including bubble quartz (e.g., quartz with fluid inclusions), alumina, yttria, or sapphire. The upper dome 128 may also be formed from coated metals or ceramics. The lower dome 114 may be formed from an optically transparent or translucent material such as quartz. The lower dome 114 is coupled to, or is an integral part of, the chamber body 101. The chamber body 101 may include a base plate 160 that supports the upper dome 128.

An array of radiant heating lamps 102 is disposed below the lower dome 114 for heating, among other components, a backside 104 of a substrate support 107 disposed within the processing chamber 100. During deposition, the substrate 108 may be brought into the processing chamber 100 and positioned onto the substrate support 107 through a loading port 103. The lamps 102 are adapted to the heat the substrate 108 to a predetermined temperature to facilitate thermal decomposition of process gases supplied into the processing chamber to deposit a material on onto the upper surface 116 of the substrate 108. In one example, the material deposited onto the substrate 108 may be a group III, group IV, and/or group V material, or a material which includes a group III, group IV, and/or group V dopant. For example, the deposited material may be one or more of gallium arsenide, gallium nitride, or aluminum gallium nitride. The lamps 102 may be adapted to heat the substrate 108 to a temperature of about 300 degrees Celsius to about 1200 degrees Celsius, such as about 300 degrees Celsius to about 950 degrees Celsius.

The lamps 102 may include bulbs 141 surrounded by an optional reflector 143 disposed adjacent to and beneath the lower dome 114 to heat the substrate 108 as the process gas passes thereover to facilitate the deposition of the material onto the upper surface 116 of the substrate 108. The lamps 102 are arranged in annular groups of increasing radius around a shaft 132 of the substrate support 107. The shaft 132 is formed from quartz and contains a hollow portion or cavity therein, which reduces lateral displacement of radiant energy near the center of the substrate 108, thus facilitating uniform irradiation of the substrate 108.

In one embodiment, each lamp 102 is coupled to a power distribution board (not shown) through which power is supplied to each lamp 102. The lamps 102 are positioned within a lamphead 145 which may be cooled during or after processing by, for example, a cooling fluid introduced into channels 149 located between the lamps 102. The lamphead 145 conductively cools the lower dome 114 due in part to the close proximity of the lamphead 145 to the lower dome 114. The lamphead 145 may also cool the lamp walls and walls of the reflectors 143. If desired, the lampheads 145 may be in contact with the lower dome 114.

The substrate support 107 is shown in an elevated processing position, but may be moved vertically by an actuator (not shown) to a loading position below the processing position to allow lift pins 105 to contact the lower dome 114. The lift pins 105 pass through holes 111 in the substrate support 107 and raise the substrate 108 from the substrate support 107. A robot (not shown) may then enter the processing chamber 100 to engage and remove the substrate 108 therefrom through the loading port 103. A new substrate is placed on the substrate support 107, which then may be raised to the processing position to place the substrate 108, with upper surface 116 wherein devices mostly formed thereon facing up, in contact with a front side 110 of the substrate support 107.

The substrate support 107 disposed in the processing chamber 100 divides the internal volume of the processing chamber 100 into a process gas region 156 (above the front side 110 of the substrate support 107) and a purge gas region 158 (below the substrate support 107). The substrate support 107 is rotated during processing by a central shaft 132 to minimize the effects of thermal and process gas flow spatial non-uniformities within the processing chamber 100, and thus facilitate uniform processing of the substrate 108. The substrate support 107 is supported by the central shaft 132, which moves the substrate 108 in an up and down direction 134 during loading and unloading, and in some instances, during processing of the substrate 108. The substrate support 107 may be formed from a material having low thermal mass or low heat capacity, so that energy absorbed and emitted by the substrate support 107 is minimized. The substrate support 107 may be formed from silicon carbide or graphite coated with silicon carbide to absorb radiant energy from the lamps 102 and rapidly conduct the radiant energy to the substrate 108. In one embodiment, the substrate support 107 is shown in FIG. 1 as a ring having a central opening to facilitate exposure of the center of the substrate to the thermal radiation generated by the lamps 102. The substrate support 107 may support the substrate 108 from the edge of the substrate 108. In another embodiment, the substrate support 107 may also be a disk member that has no central opening. In yet another embodiment, the substrate support 107 may also be a disk-like or platter-like substrate support, or a plurality of pins extending from a respective finger, for example, three pins or five pins.

In one embodiment, the upper dome 128 and the lower dome 114 are formed from an optically transparent or translucent material such as quartz. The upper dome 128 and the lower dome 114 are thin to minimize thermal memory. In one embodiment, the upper dome 128 and the lower dome 114 may have a thickness between about 3 mm and about 10 mm, for example about 4 mm. The upper dome 128 may be thermally controlled by introducing a thermal control fluid, such as a cooling gas, through an inlet portal 126 into a thermal control space 136, and withdrawing the thermal control fluid through an exit portal 130. In some embodiments, a cooling fluid circulating through the thermal control space 136 may reduce deposition on an inner surface of the upper dome 128.

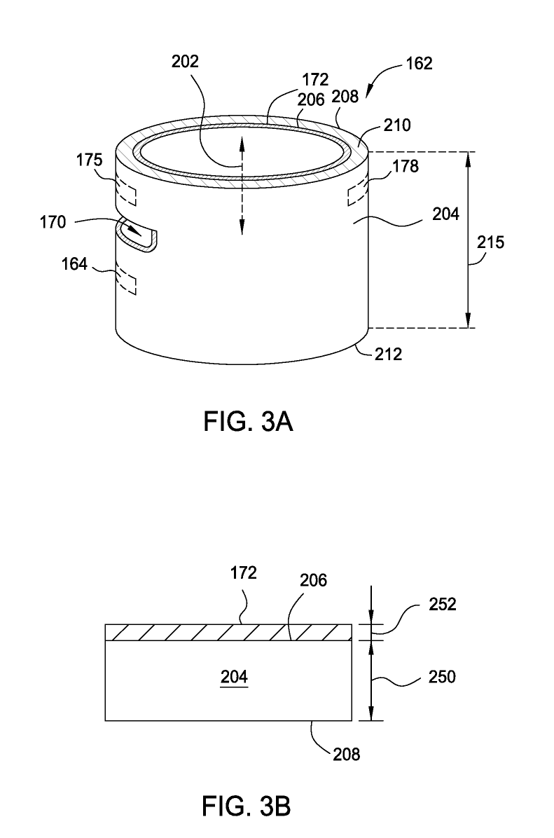

A liner assembly 162 may be disposed within the chamber body 101 and is surrounded by the inner circumference of the base plate 160. The liner assembly 162 may be formed from a process-resistant material and generally shields the processing volume (i.e., the process gas region 156 and purge gas region 158) from metallic walls of the chamber body 101. The metallic walls may react with precursors and cause contamination in the processing volume. An opening 170, such as a slit valve, may be disposed through the liner assembly 162 and aligned with the loading port 103 to allow for passage of the substrate 108. While the liner assembly 162 is shown as a single piece, it is contemplated that the liner assembly 162 may be formed from multiple pieces. In one embodiment, the liner assembly 162 may have a coating layer 302 coated on an outer wall of the liner assembly 162 that faces the base plate 160. Alternatively, the coating layer 302 may be coated on an inner wall of the liner assembly 162 that faces the process gas region 156 (above the front side 11 of the substrate support 107) and the purge gas region 158 (below the substrate support 107), which will be further described below with referenced to FIG. 3A-3B.

The coating layer 302 covers an outer circumference of the liner assembly 162. The liner assembly 162 along with the coating layer 301 may be shaped as a cylindrical ring having a cutout portion (e.g., opening 170 in the liner assembly 162 and the opening 174 in the coating layer 302) adapted to allow for substrate transport through the liner assembly 162. Additionally cut-out portions may be formed to allow gas provided from gas port 175, 178, 164 to flow through the liner assembly 162 and into the processing chamber 100, which will be discussed in further detail below. In the embodiment depicted in FIG. 1, the liner assembly 162 including the coating layer 302 extends above the loading port 103, however, it is contemplated that the area immediately above and bounding the loading port 103 may be part of the lower dome 114. In another embodiment, the coating layer 302 may be supported by a portion (not shown) of the liner assembly 162 that extends radially inward from an inner radius of the liner assembly 162. The portion, or ledge, may be discontinuous comprising a plurality of segments.

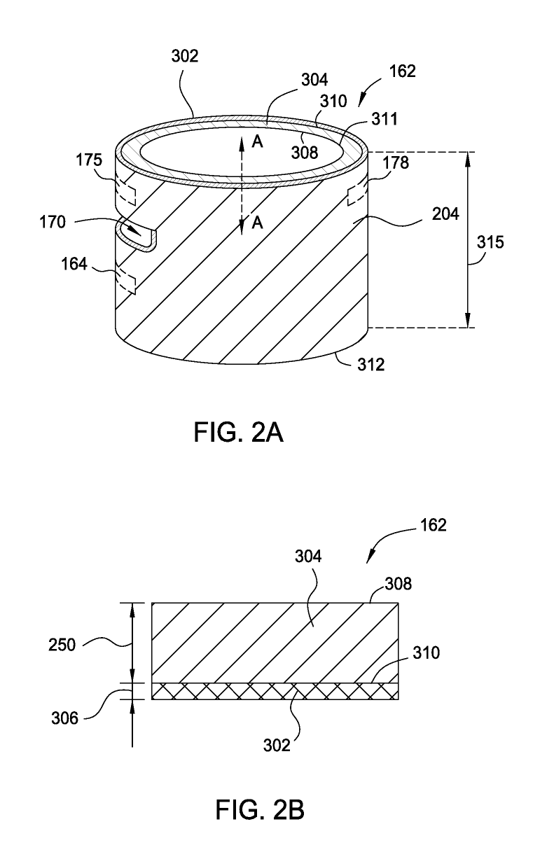

In one embodiment, the liner assembly 162 may be fabricated from an optical transparent or translucent material, such as glass, quartz, including bubble quartz (e.g., quartz with fluid inclusions), sapphire, opaque quartz, and the like. Alternatively, the liner assembly 162 may be fabricated by a metallic material, such as aluminum containing materials if the material is protected from corrosion. The coating layer 302 disposed on the liner assembly 162 may be a dielectric material. In one embodiment, the coating layer 302 is an opaque material opaque at one or more light radiation wavelengths ranging between about 200 nm and about 5000 nm. The opaque material coating the liner assembly 162 may maintain radiation within the processing chamber 100 so as to keep radiation from escaping from the liner assembly 162, thus transmitting the radiation back to the process gas region 156 and, in the embodiment of coating on an inner circumference of the liner assembly 162, the purge gas region 158. Details regarding selection of the materials and functions of the coating layer 302 disposed on the liner assembly 162 will be further discussed below with referenced to FIGS. 2A-2B.

It is noted that the term “opaque” used herein to describe a material generally refers to that the material is substantially not transparent or translucent. A material may be considered opaque when light transmitted therethrough is not sufficient to interfere with (i.e., substantially effect) the thermal radiation within in the processing chamber. In one embodiment, an opaque material as described herein may have a transmissivity of less than 1 percent, such as less than 10⁻² percent, for example less than 10⁻⁴ percent.

An optical pyrometer 118 may be disposed at a region above the upper dome 128. The optical pyrometer 118 measures a temperature of the upper surface 116 of the substrate 108. Heating the substrate 108 from the front side 110 of the substrate support 107 in this manner provides for more uniform heating due to the absence of die patterns. As a result of being on the side opposite that of the source ration and being effectively shielded from the source radiation, the optical pyrometer 118 only senses radiation from the hot substrate 108, with minimal background radiation from the lamps 102 directly reaching the optical pyrometer 118. In certain embodiments, multiple pyrometers may be used and may be disposed at various locations above the upper dome 128.

A reflector 122 may be optionally placed outside the upper dome 128 to reflect infrared light that is radiating from the substrate 108 or transmitted by the substrate 108 back onto the substrate 108. Due to the reflected infrared light, the efficiency of the heating will be improved by containing heat that could otherwise escape the processing chamber 100. The reflector 122 can be made of a metal such as aluminum or stainless steel. The reflector 122 can have the inlet portal 126 and exit portal 130 to carry a flow of a fluid such as water for cooling the reflector 122. If desired, the reflection efficiency can be improved by coating a reflector area with a highly reflective coating, such as a gold coating.

A plurality of thermal radiation sensors 140, which may be pyrometers or light pipes, such as sapphire light pipes, may be disposed in the lamphead 145 for measuring thermal emissions of the substrate 108. The sensors 140 are typically disposed at different locations in the lamphead 145 to facilitate viewing (i.e., sensing) different locations of the substrate 108 during processing. In embodiments using light pipes, the sensors 140 may be disposed on a portion of the chamber body 101 below the lamphead 145. Sensing thermal radiation from different locations of the substrate 108 facilitates comparing the thermal energy content, for example the temperature, at different locations of the substrate 108 to determine whether temperature anomalies or non-uniformities are present. Such temperature non-uniformities can result in non-uniformities in film formation, such as thickness and composition. At least two sensors 140 are used, but more than two may be used. Different embodiments may use any number of additional sensors 140. It is noted that these sensors 140 being on the same sides of the substrate 108 as the radiant heating sources may require a correction technique to compensate for the back scattered source radiation.

Each sensor 140 views a zone of the substrate 108 and senses the thermal state of that zone. The zone may be oriented radially in some embodiments. For example, in embodiments where the substrate 108 is rotated, the sensors 140 may view, or define, a central zone in a central portion of the substrate 108 having a center substantially the same as the center of the substrate 108, with one or more zones surrounding the central zone and concentric therewith. It is not required that the zones be concentric and radially oriented. In some embodiments, zones may be arranged at different locations of the substrate 108 in non-radial fashion.

The sensors 140 are typically disposed between the lamps 102, for example in the channels 149, and are usually oriented substantially normal to the upper surface 116 of the substrate 108. In some embodiments the sensors 140 are oriented normal to the substrate 108, while in other embodiments, the sensors 140 may be oriented in slight departure from normal. An orientation angle within about 5° of normal is most frequently used.

The sensors 140 may be attuned to the same wavelength or spectrum, or to different wavelengths or spectra. For example, substrates used in the processing chamber 100 may be compositionally homogeneous, or they may have domains of different compositions. Using sensors 140 attuned to different wavelengths may allow monitoring of substrate domains having different composition and different emission responses to thermal energy. In one embodiment, the sensors 140 are attuned to infrared wavelengths, for example about 3 μm.

Process gas supplied from a process gas supply source 173 is introduced into the process gas region 156 through a process gas inlet port 175 formed in the sidewall of the base plate 160. Additional openings (not shown) may also be formed in the liner assembly 162 and the coating layer 302 to allow gas to flow therethrough. The process gas inlet port 175 is configured to direct the process gas in a generally radially inward direction. During the film formation process, the substrate support 107 is located in the processing position, which is adjacent to and at about the same elevation as the process gas inlet port 175, thereby allowing the process gas to flow along flow path 169 defined across the upper surface 116 of the substrate 108. The process gas exits the process gas region 156 (along flow path 165) through a gas outlet port 178 located on the opposite side of the processing chamber 100 relative to the process gas inlet port 175. Removal of the process gas through the gas outlet port 178 may be facilitated by a vacuum pump 180 coupled thereto. As the process gas inlet port 175 and the gas outlet port 178 are aligned to each other and disposed approximately at the same elevation, it is believed that such a parallel arrangement will enable a generally planar, uniform gas flow across the substrate 108. Further radial uniformity may be provided by the rotation of the substrate 108 through the substrate support 107.

Purge gas supplied from a purge gas source 163 is introduced to the purge gas region 158 through a purge gas inlet port 164 formed in the sidewall of the base plate 160. The purge gas inlet port 164 is disposed at an elevation below the process gas inlet port 175. The purge gas inlet port 164 is configured to direct the purge gas in a generally radially inward direction. If desired, the purge gas inlet port 164 may be configured to direct the purge gas in an upward direction. During the film formation process, the substrate support 107 is located at a position such that the purge gas flows along flow path 161 across a back side 104 of the substrate support 107. Without being bound by any particular theory, the flowing of the purge gas is believed to prevent or substantially avoid the flow of the process gas from entering into the purge gas region 158, or to reduce diffusion of the process gas entering the purge gas region 158 (i.e., the region under the substrate support 107). The purge gas exits the purge gas region 158 (along flow path 166) and is exhausted out of the process chamber through the gas outlet port 178 located on the opposite side of the processing chamber 100 relative to the purge gas inlet port 164.

Similarly, during the purging process the substrate support 107 may be located in an elevated position to allow the purge gas to flow laterally across the back side 104 of the substrate support 107. It should be appreciated by those of ordinary skill in the art that the process gas inlet port, the purge gas inlet port and the gas outlet port are shown for illustrative purposes, since the position, size, or number of gas inlets or outlet port etc., may be adjusted to further facilitate a uniform deposition of material on the substrate 108.

During processing, a controller 182 receives data from the sensors 140 and separately adjusts the power delivered to each lamp 102, or individual groups of lamps or lamp zones, based on the data. The controller 182 may include a power supply 184 that independently powers the various lamps 102 or lamp zones. The controller 182 can be configured to produce a desired temperature profile on the substrate 108, and based on comparing the data received from the sensors 140, the controller 182 may adjust the power to lamps and/or lamp zones to conform the observed (i.e., sensed) thermal data indicating of the lateral temperature profile of the substrate with to the desired temperature profile. The controller 182 may also adjust power to the lamps and/or lamp zones to conform the thermal treatment of one substrate to the thermal treatment of another substrate, to prevent chamber performance drift over time.

FIG. 2A depicted a schematic top isometric view of the liner assembly 162 that may be used in the processing chamber 100 depicted in FIG. 1. The liner assembly 162 includes a liner body 304 having a generally cylindrical in form. The liner assembly 162 has an inner wall 308 and an outer all 310. As further depicted in cross sectional view of the liner body 304 in FIG. 2B, the inner wall 308 and the outer wall 310 define a thickness 250 of the liner body 304. In one embodiment, the thickness 250 of the liner body 304 ranges from between about 5 mm and about 100 mm, such as between about 5 mm and about 50 mm. Referring back to FIG. 2A, the opening 174 formed in the liner body 304 through the inner wall 308 to the outer wall 310 allows passage of the substrate 108 into and out of the processing chamber 100. Additionally, the opening 174 has a size substantially matching the size of the opening 170 of the loading port 103 formed in the base plate 160.

The liner body 304 has a top surface 311 and a bottom surface 312 connected by the inner wall 308 and the outer wall 310. The liner body 304 of the liner assembly 162 has a length 315 sized to fit the dimensions of the base plate 160 so as to slip inside the base plate 160 and prevent the base plate 160 from being exposed to the interior reacting region of the processing chamber 100 of the processing chamber 100. In one embodiment, the length 315 of the liner assembly 162 may have a range between about 10 mm and about 200 mm, such as between about 70 mm and about 120 mm.

As depicted in FIG. 2B, the coating layer 302 may be formed on the inner wall 308 of the liner assembly 162 so as to absorb light impinging through the liner assembly 162. In contrast, the coating layer 302 selected to be coated on the liner assembly 162 may be a material that is opaque at one or more wavelengths in the range of between about 200 nm and about 5000 nm, which is the wavelengths of the radiation generated by the lamps 102 for providing thermal energy to the 25 μm and about 100 μm, such as about 25 μm. In one embodiment, suitable materials of the opaque materials for the coating layer 302 include silicon carbide, glassy carbon, carbon black, bubble quartz (e.g., quartz with fluid inclusions), graphitized carbon black, graphite, black quartz, bubble quartz, silicon and black pigmented slip coating, such as Aremco 840 series and the like. The opaque materials selected to form the coating layer 302 may be coated onto the liner assembly 162 may any suitable coating/deposition techniques such as CVD, PVD, plasma sprayed, sintered dipped or painted slurries or precursors, spin-coating and sintered, flame spraying, brush coating, dip coating, roller coating, silk screen coating or any other suitable techniques. In an exemplary embodiment depicted herein, the coating layer 302 is a silicon carbide layer deposited on a CVD material.

The opaque material selected to coat the liner assembly 162 may maintain radiation within the processing chamber 100 and keep the radiation from being transmitted back to the process gas region 156 and the purge gas region 158. It is believed that selection of the opaque material for the coating layer 302 may provide a high absorptivity to radiation impinging on the liner assembly 162, thus preventing background optical noise that may possibly reflect back to the substrate 108, thereby increasing accuracy of temperature measurement of the pyrometer 118. In one embodiment, the coating layer 301 may transmit less than 10 percent of the thermal radiation in the wavelength range of interest, such as between about 200 nm and about 5000 nm, impinging on the coating layer 302. Furthermore, it is believed that light scattering or transmission characteristics of the thermal radiation energy may also interfere emission and absorption of the temperature measurement of the pyrometer 118 from the substrate 108. Accordingly, the opaque material for the coating layer 302 may prevent thermal radiance from reaching or reflecting back to the substrate 108 or to the pyrometer 118.

FIG. 3A depicted a schematic top isometric view of the liner assembly 162 that may be used in the processing chamber 100 depicted in FIG. 1. The liner assembly 162 includes a liner body 204, similar to the liner body 304 depicted in FIGS. 3A and 3B, having a generally cylindrical in form. Similarly, the liner body 204 has an inner wall 206 and an outer all 208. As further depicted in FIG. 3B, the inner wall 206 and the outer wall 208 define a thickness 250 of the liner body 204. In one embodiment, the thickness 250 of the liner body 204 ranges from between about 5 mm and about 100 mm, such as between about 5 mm and about 50 mm. Referring back to FIG. 3A, the liner body 204 has a top surface 210 and a bottom surface 212 connected by the inner wall 206 and the outer wall 208. The liner body 204 of the liner assembly 162 has a length 215 sized to fit the dimensions of the base plate 160 so as to slip inside the base plate 160 and prevent the base plate 160 from being exposed to the interior reacting region of the processing chamber 100 of the processing chamber 100. In one embodiment, the length of the liner assembly 162 may have a range about 10 mm and about 200 mm, such as between about 70 mm and about 120 mm.

Instead of having the coating layer 302 coated on the outer wall 310 of the liner body 304, the embodiment depicted in FIGS. 3A and 3B, a coating layer 172 is coated on the inner wall 206 of the liner assembly 162 so as to absorb light impinging the liner assembly 162. The coating layer 172 selected to be coated on the liner assembly 162 may be a material that is opaque at one or more wavelengths in the range of between about 200 nm and about 5000 nm, similar to the coating layer 302 depicted above with reference to FIGS. 1-2B. The coating layer 172 may have a thickness 252 between about 5 μm and about 100 μm, such as about 25 μm. In one embodiment, suitable materials of the opaque materials for the coating layer 172 include silicon carbide, glassy carbon, carbon black, graphitized carbon black, graphite, black quartz, bubble quartz, silicon and black pigmented slip coating, such as Aremco 840 series and the like. The opaque materials selected to form the coating layer 172 may be coated onto the liner assembly 162 may any suitable coating/deposition techniques such as CVD, PVD, plasma sprayed, sintered dipped or painted slurries or precursors, spin-coating and sintered, flame spraying, brush coating, dip coating, roller coating, silk screen coating or any other suitable techniques. In an exemplary embodiment depicted herein, the coating layer 302 is a silicon carbide layer deposited on a CVD material.

It is noted that the coating layers 302, 172 may not only coated on the outer wall or inner wall of the liner assembly, but also the top and bottom surfaces and any suitable places in the liner body as needed.

While the foregoing is directed to embodiments of the present invention, other and further embodiments of the invention may be devised without departing from the basic scope thereof, and the scope thereof is determined by the claims that follow.

1. A liner assembly for use in a semiconductor processing chamber, comprising:
a liner body having a cylindrical ring form; and
a coating layer disposed on the liner body, wherein the coating layer is opaque at one or more wavelengths between about 200 nm and about 5000 nm.

2. The liner assembly of claim 1, wherein the liner body is fabricated from an optically transparent or translucent material.

3. The liner assembly of claim 1, wherein the liner body is fabricated from quartz.

4. The liner assembly of claim 1, wherein the coating layer is fabricated from a group consisting of silicon carbide, glassy carbon, carbon black, graphitized carbon black, graphite, black quartz, bubble quartz, silicon and black pigmented slip coating.

5. The liner assembly of claim 1, wherein the coating layer has a thickness between about 5 μm and about 100 μm.

6. The liner assembly of claim 1, wherein the coating layer is formed on the inner wall of the liner assembly by CVD, PVD, plasma spray, sintered dipping, spin-coating and sintering, flame spraying, brush coating, dip coating, roller coating and silk screen coating.

7. The liner assembly of claim 1, wherein the liner body including a top surface and a bottom surface connected by an inner wall and an outer wall.

8. The liner assembly of claim 7, wherein the coating layer is disposed on the inner wall or outer wall of the liner body.

9. An epitaxy deposition chamber comprising the liner assembly of claim 1.

10. The liner assembly of claim 9, wherein the liner assembly is removable from the processing chamber.

11. An apparatus for depositing a dielectric layer on a substrate, comprising:
a processing chamber having an interior volume defined in a chamber body of the processing chamber; and
a liner assembly disposed in the processing chamber, wherein the liner assembly further comprises:
a liner body having a cylindrical ring form; and
a coating layer coating an outer wall of the liner body and facing the chamber body, wherein the coating layer is opaque at one or more wavelengths between about 200 nm and about 5000 nm.

12. The apparatus of claim 11, wherein liner body is fabricated from an optically transparent or translucent material.

13. The apparatus of claim 11, wherein liner body is fabricated from quartz.

14. The apparatus of claim 11, wherein the coating layer is fabricated from a material selected from the group consisting of silicon carbide, glassy carbon, carbon black, graphitized carbon black, graphite, black quartz, bubble quartz, silicon and black pigmented slip coating.

15. The apparatus of claim 11, wherein the coating layer has a thickness between about 5 μm and about 100 μm.

16. The apparatus of claim 11, wherein the liner assembly is removable from the processing chamber.

17. The apparatus of claim 11, wherein the coating layer is formed on an inner the liner body and facing the interior volume of the processing chamber.

18. The apparatus of claim 11, wherein the processing chamber is an epitaxy deposition chamber.

19. An apparatus for depositing a dielectric layer on a substrate, comprising:
a processing chamber having an interior volume defined in a chamber body of the processing chamber; and
a liner assembly disposed in the processing chamber, wherein the liner assembly further comprises:
a liner body having a cylindrical ring form; and
a coating layer coating on an outer wall of the liner body and facing the chamber body, wherein the coating layer is opaque at one or more wavelengths between about 200 nm and about 5000 nm, the coating layer fabricated from a material selected from the silicon carbide, glassy carbon, carbon black, graphitized carbon black, graphite, black quartz, bubble quartz, silicon and black pigmented slip coating.

20. The apparatus of claim 19, wherein processing chamber is an epitaxy deposition chamber.
